(19) United States
(12) Patent Application Publication
(10) Pub. No.: US 2025/0048687 A1
(43) Pub. Date: Feb. 6, 2025

(54) SEMICONDUCTOR DEVICE AND MANUFACTURING METHOD FOR SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroki OKUYAMA, Yokohama Kanagawa (JP); Kenichi OHASHI, Kawasaki Kanagawa (JP); Kentaro MORI, Fujisawa Kanagawa (JP); Kazushiro NOMURA, Kawasaki Kanagawa (JP); Aya MURAYOSHI, Ichihara Chiba (JP)

(21) Appl. No.: 18/593,362

(22) Filed: Mar. 1, 2024

(30) Foreign Application Priority Data
Jul. 31, 2023 (JP) 2023-124567

(51) Int. Cl. H01L 29/06; H01L 21/784; H01L 23/00; H01L 23/495; H01L 29/78

(52) U.S. Cl. CPC H01L 29/0657; H01L 21/784; H01L 23/49513; H01L 24/05; H01L 24/32; H01L 29/7827; H01L 2224/05558; H01L 2224/32245; H01L 2924/10253; H01L 2924/13091

(57) ABSTRACT

According to one embodiment, a semiconductor device has a substrate with an upper face and a lower face. The substrate includes a first end portion near a first edge and a second end portion near a second edge. An element region is between the first end portion and the second end portion. A first ridge portion protrudes from a first portion of the substrate that is between the first end portion and the element portion. The first ridge portion is on the lower face. A second ridge portion protrudes from a second portion of the substrate that is between the second end portion and the element portion in the second direction. The second ridge portion is on the lower face.

### CROSS-REFERENCE TO RELATED APPLICATION(S)

This application is based upon and claims the benefit of priority from Japanese Patent Application No. 2023-124567, filed Jul. 31, 2023, the entire contents of which are incorporated herein by reference.

### FIELD

Embodiments described herein relate generally to a semiconductor device and a method of manufacturing a semiconductor device.

### BACKGROUND

At present, consideration is being given to reducing the thickness of the semiconductor substrate used for a semiconductor device that has a transistor or the like therein. However, when a semiconductor substrate becomes thinner, there is a possibility of its strength being reduced.

### BRIEF DESCRIPTION OF THE DRAWINGS

FIG. 1 is a schematic cross-sectional view of a semiconductor device according to an embodiment.

FIG. 2 is a schematic plan view of a semiconductor device according to an embodiment.

FIG. 3 is a schematic cross-sectional view of a semiconductor device according to an embodiment.

FIG. 4 is a schematic plan view of a semiconductor device according to an embodiment.

FIG. 5 is a schematic cross-sectional view of a semiconductor device according to an embodiment.

FIG. 6 is a schematic plan view of semiconductor device according to a modification of an embodiment.

FIGS. 7A and 7B are schematic views depicting aspects of a manufacturing method according to an embodiment.

FIGS. 8A and 8B are schematic views depicting aspects of a manufacturing method according to an embodiment.

FIGS. 9A to 9C are schematic views depicting aspects of a manufacturing method according to an embodiment.

FIGS. 10A and 10B are schematic views depicting aspects of a manufacturing method according to an embodiment.

FIGS. 11A to 11C are schematic views depicting aspects of a manufacturing method according to an embodiment.

FIGS. 12A and 12B are schematic views illustrating aspects related to a pick-up of a semiconductor device.

FIGS. 13A and 13B are schematic plan views depicting aspects related to a pushing up position for picking up a semiconductor device.

### DETAILED DESCRIPTION

In general, according to one embodiment, a semiconductor device includes a semiconductor substrate having an upper face and a lower face. The upper face is opposite of the lower face in a first direction. The semiconductor substrate includes a first end portion near a first edge of the semiconductor substrate, a second end portion near a second edge of the semiconductor substrate, the first edge and the second edge being separated from each other in a second direction orthogonal to the first direction, and an element region between the first end portion and the second end portion in the second direction. The substrate further includes a first ridge portion that protrudes in the first direction from a first portion that is between the first end portion and the element portion in the second direction. The first ridge portion is on the lower face and extends along the lower face in a third direction perpendicular to the first direction and the second direction. The substrate also includes a second ridge portion that protrudes in the first direction from a second portion that is between the second end portion and the element portion in the second direction. The second ridge portion is on the lower face and extends along the lower face in the third direction.

Hereafter, certain example embodiments of the present disclosure will be described while referring to the drawings.

The drawings are schematic or conceptual, and relationships between thicknesses and widths of portions, ratios of sizes between portions, and the like, are not necessarily the same as actual relationships and ratios. Even when representing the same portion, the portion may be represented with differing dimensions or ratios depending on the drawing.

In the present specification and the drawings, the same reference sign is allotted to those elements that are the same as already described, and a detailed description of repeated aspects may be omitted as appropriate.

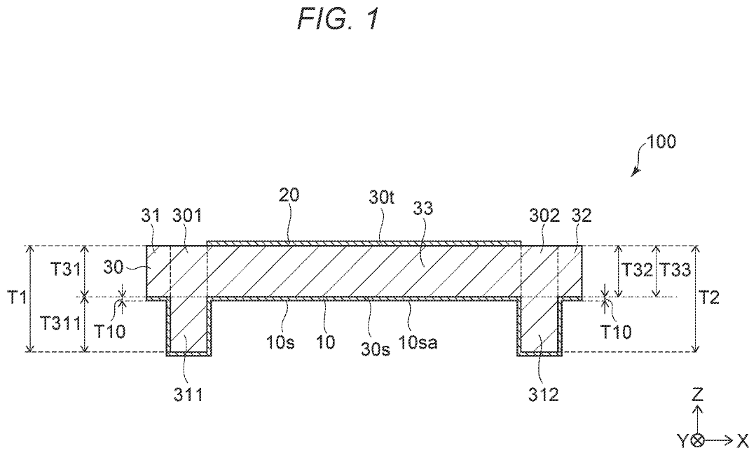

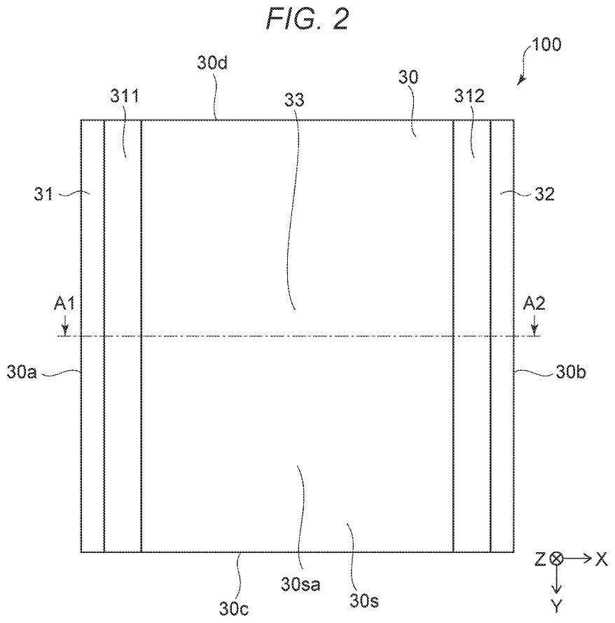

FIG. 1 depicts aspects of a semiconductor device according to an embodiment. FIG. 2 also depicts aspects of the semiconductor device according to the embodiment.

FIG. 2 shows a semiconductor device 100 according to the embodiment as seen from below. FIG. 1 represents a cross-section of the semiconductor device 100 along an A1-A2 line in FIG. 2.

As represented in FIG. 1, the semiconductor device 100 has a first electrode 10, a second electrode 20, and a semiconductor substrate 30. In FIG. 2, the depiction of the first electrode 10 is omitted from the view.

The semiconductor substrate 30 has an upper face 30t and a lower face 30s. In the description, a direction from the lower face 30s toward the upper face 30t is a Z direction. The Z direction is the thickness direction of the semiconductor substrate 30 and is orthogonal to the upper face 30t. For the sake of description, the direction from the lower face 30s toward the upper face 30t is called “up”, and the opposite direction is called “down”. These directions are based on a relative positional relationship with the upper face 30t from the lower face 30s and are not necessarily related to the direction of gravitational force.

The upper face 30t extends in an X-Y plane. The upper face 30t is substantially planar in this example. The lower face 30s is not fully planar and includes what may be referred to as irregularities or non-planar portions. In particular, regions in near opposite ends/sides of the semiconductor substrate 30 are thickened. The upper face 30t is flatter than the lower face 30s.

The semiconductor substrate 30 includes a first end portion 31, a second end portion 32, and an element portion 33. The first end portion 31 and the second end portion 32 are opposite end/edge regions of the semiconductor substrate 30 in the X direction. The second end portion 32 is separated from the first end portion 31 in the X direction.

The element portion 33 is positioned between the first end portion 31 and the second end portion 32. The element portion 33 is a region in which a semiconductor element (e.g., a device element) such as a transistor can be formed. A current flows via the element portion 33 (the semiconductor element) between the first electrode 10 and the second electrode 20 in accordance with an operation of the semiconductor element. For the sake of depictional convenience, the particular depiction of the structure of the semiconductor element inside the element portion 33 is omitted from FIG. 1.

As represented in FIG. 1, the semiconductor substrate 30 has a first portion 301 and a first ridge portion 311. The first portion 301 is positioned between the first end portion 31 and the element portion 33. The first ridge portion 311 protrudes farther downward than the first end portion 31 and the element portion 33 from the first portion 301.

The semiconductor substrate 30 has a second portion 302 and a second ridge portion 312. The second portion 302 is positioned between the second end portion 32 and the element portion 33. The second ridge portion 312 protrudes farther downward than the second end portion 32 and the element portion 33 from the second portion 302.

The upper face 30t of the semiconductor substrate 30 is formed of the upper face of the first end portion 31, the upper face of the second end portion 32, the upper face of the element portion 33, the upper face of the first portion 301, and the upper face of the second portion 302. The lower face 30s of the semiconductor substrate 30 is formed of the lower face of the first end portion 31, the lower face of the second end portion 32, the lower face of the element portion 33, the lower face and side faces of the first ridge portion 311, and the lower face and side faces of the second ridge portion 312.

Generally, the thickness T32 (a length along the Z direction) of the second end portion 32 is the same as the thickness T31 (a length along the Z direction) of the first end portion 31. Generally, the thickness T33 (a length along the Z direction) of the element portion 33 is the same as the thickness T31 of the first end portion 31. The thickness T33 of the element portion 33 is, for example, 30 μm or less. In some examples, the element portion 33 may be thinner or thicker than the first end portion 31. Typically, the thicknesses of the first portion 301 and the second portion 302 are the same as the thickness T33 of the element portion 33.

The thickness T33 of the element portion 33 is less than the thickness T1 at a position at which the first ridge portion 311 is provided. The thickness T1 is a summed total of the thickness (the length along the Z direction) of the first portion 301 and the thickness (the length along the Z direction) of the first ridge portion 311. The thickness T1 is, for example, 50 μm or greater.

Typically, the thickness T2 at a position at which the second ridge portion 312 is provided is the same as the thickness T1 in the corresponding position of the first ridge portion 311. The thickness T2 is a summed total of the thickness (the length along the Z direction) of the second portion 302 and the thickness (the length along the Z direction) of the second ridge portion 312.

In this example, the width (a length along the X direction) of the first ridge portion 311 is greater than the width (a length along the X direction) of the first end portion 31. Also, the width (a length along the X direction) of the second ridge portion 312 is greater than the width (a length along the X direction) of the second end portion 32. However, examples are not limited to this, and the width of the first ridge portion 311 may be less than the width of the first end portion 31, and, similarly, the width of the second ridge portion 312 may be less than the width of the second end portion 32.

The second electrode 20 is provided above the element portion 33. As depicted, the second electrode 20 is provided only above the element portion 33. The second electrode 20 is electrically connected to the semiconductor element in the element portion 33.

The first electrode 10 is provided on the lower face 30s of the semiconductor substrate 30 and is also electrically connected to the semiconductor element in the element portion 33. The first electrode 10 covers approximately the whole of the lower face 30s. The first electrode is also in contact with approximately the whole of the lower face 30s. That is, the first electrode 10 is provided as a continuous layer along the element portion 33, the first ridge portion 311, the second ridge portion 312, the first end portion 31, and the second end portion 32. As depicted, the first electrode 10 has approximately the same layer thickness on the lower face 30s portions.

The thickness T10 of the first electrode 10 is less than the thickness T311 of the first ridge portion 311. The thickness T10 of the first electrode 10 may be constant (or substantially so) along the lower face 30s of the semiconductor substrate 30. A lower face 10s of the first electrode 10 has a shape (non-planar shape) substantially following the shape of the lower face 30s of the semiconductor substrate 30.

As represented in FIG. 2, the semiconductor substrate 30 is of a rectangular form when seen in plan view. The semiconductor substrate 30 has a first side 30a extending in the Y direction, a second side 30b extending in the Y direction, a third side 30c extending in the X direction, and a fourth side 30d extending in the X direction. The first side 30a is positioned in the first end portion 31. The second side 30b is positioned in the second end portion 32. One end of the third side 30c is connected to one end of the first side 30a, and the other end of the third side 30c is connected to one end of the second side 30b. One end of the fourth side 30d is connected to the other end of the first side 30a, and the other end of the fourth side 30d is connected to the other end of the second side 30b.

Each of the first end portion 31, the first ridge portion 311, the second end portion 32, and the second ridge portion 312 extends in the Y direction fully from the third side 30c to the fourth side 30d.

For example, the first side 30a may be longer than the third side 30c and the fourth side 30d. The second side 30b may be longer than the third side 30c and the fourth side 30d. That is, the first ridge portion 311 and the second ridge portion 312 may be provided on long dimension sides of the semiconductor substrate 30.

Also, as represented in FIG. 2, no protruding portion is provided anywhere within the region 30sa of the lower face 30s. The region 30sa is between the first ridge portion 311 and the second ridge portion 312 in the X direction when seen in plan view. That is, the whole of the region 30sa is recessed beyond the first ridge portion 311 and the second ridge portion 312.

In other words, as shown in FIG. 1, the semiconductor substrate 30 does not include a protruding portion arranged in the area between the first ridge portion 311 and the second ridge portion 312 in the X direction. That is, for example, there are no ridge portions connecting the Y direction ends of the first ridge portion 311 to the Y direction ends of the second ridge portion 312. That is, the element portion 33 is not fully enclosed (surrounded) by ridge portions when seen in plan view. As represented in FIG. 1, the whole region of the semiconductor substrate 30 between the first portion 301 and the second portion 302 is a constant thickness less than the thickness T1.

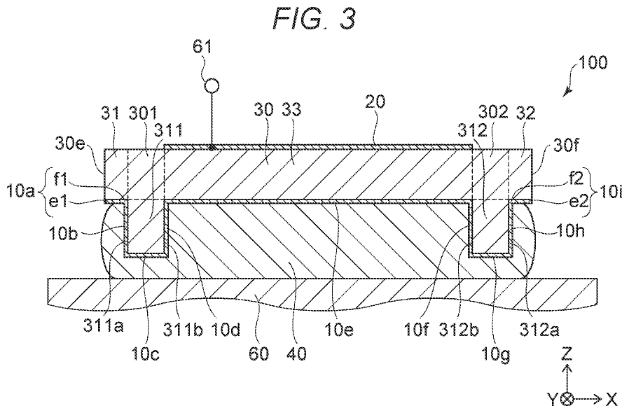

FIG. 3 is a schematic cross-sectional view exemplifying the semiconductor device 100 according to the embodiment.

In the example represented in FIG. 3, the semiconductor device 100 is mounted on a conductive member 60 using a conductive connecting material 40 (a mounting material). A conductive member 61 is electrically connected to the second electrode 20. The conductive member 61 is depicted as a schematic circuit diagram component.

The conductive member 60 is disposed below the semiconductor substrate 30 and the first electrode 10. The conductive connecting material 40 comes into contact with the lower face of the first electrode 10 and an upper face of the conductive member 60. The first electrode 10 is electrically connected to the conductive member 60 via the connecting material 40.

More specifically, the first electrode 10 includes regions 10a to 10i as represented in FIG. 3.

The region 10a comes into contact with the lower face of the first end portion 31. The region 10b comes into contact with a side face 311a of the first ridge portion 311. The region 10c comes into contact with a lower face of the first ridge portion 311. The region 10d comes into contact with a side face 311b of the first ridge portion 311. The region 10e comes into contact with the lower face of the element portion 33. The region 10f comes into contact with a side face 312b of the second ridge portion 312. The region 10g comes into contact with a lower face of the second ridge portion 312. The region 10h comes into contact with a side face 312a of the second ridge portion 312. The region 10i comes into contact with the lower face of the second end portion 32.

The connecting material 40 comes into contact with at least the region 10c, the region 10d, the region 10e, the region 10f, and the region 10g. In some examples, connecting material 40 may also come into contact with the region 10a, the region 10b, the region 10h, and the region 10i.

In this example, the connecting material 40 comes into direct contact with an inner side portion f1 of the region 10a, but does not come into direct contact with an outer side portion e1 of the region 10a. Similarly, in this example, the connecting material 40 comes into direct contact with an inner side portion f2 of the region 10i, but does not come into direct contact with an outer side portion e2 of the region 10i. Also, the connecting material 40 does not come into direct contact with either of side face 30e and side face 30f of the semiconductor substrate 30.

The thicknesses (lengths along the Z direction) of the region 10a, the region 10c, the region 10e, the region 10g, and the region 10i are the same as each other in this example.

Typically, t thicknesses (lengths along the X direction) of the region 10b, the region 10d, the region 10f, and the region 10h are the same as each other. It is sufficient that the thicknesses of the region 10a and the region 10b are the same as each other.

In an example, conductive member 60 is a lead frame die pad. In some examples, conductive member 61 may be a lead frame lead or a wire connected to a lead. For example, an on-state current of a transistor provided in the element portion 33 flows from the conductive member 60 to the conductive member 61 via the connecting material 40, the first electrode 10, the element portion 33, and the second electrode 20.

In some examples, the semiconductor device 100 may be mounted on, for example, a base substrate in which a ceramic layer and a conductive layer are stacked. That is, the conductive member 60 may be a conductive layer of a ceramic base substrate or the like.

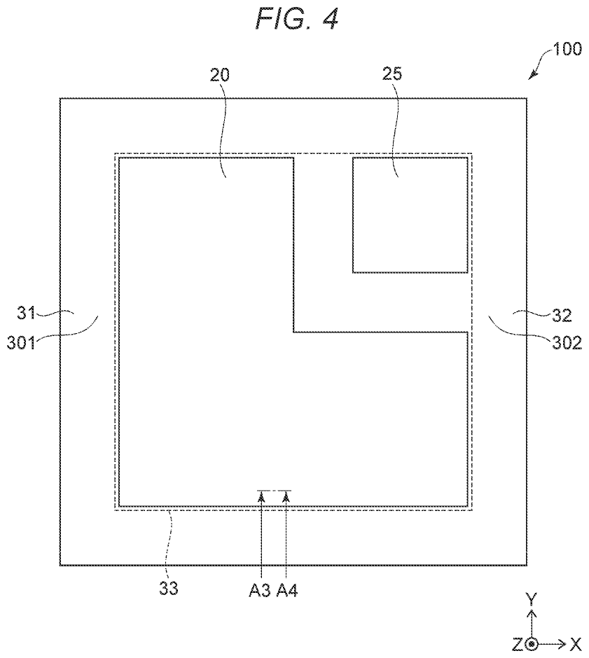

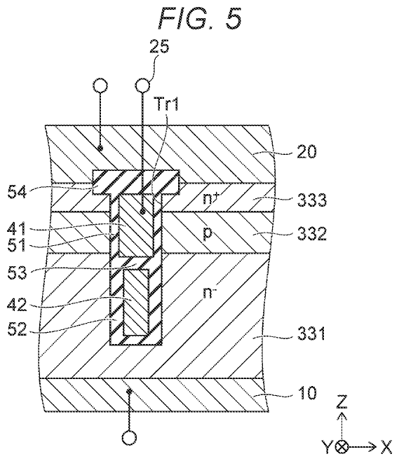

FIG. 4 is a schematic plan view exemplifying the semiconductor device according to an embodiment. FIG. 5 is a schematic cross-sectional view exemplifying the semiconductor device according to an embodiment.

Referring to FIGS. 4 and 5, one example of a semiconductor element formed on the semiconductor substrate 30 is described. In this example, the semiconductor element is a vertical metal-oxide-semiconductor field-effect transistor (MOSFET).

FIG. 4 represents a case in which the semiconductor device 100 is seen from above. FIG. 5 corresponds to a cross-section along an A3-A4 line of FIG. 4.

In FIG. 4, the second electrode 20 (a source electrode) and a third electrode 25 (a gate electrode) are provided on the upper face of the approximately rectangular element portion 33. The third electrode 25 is separated from the second electrode 20 and is smaller in area than the second electrode 20.

In FIG. 5, a first semiconductor region 331 (a drift region) of a first conductivity type, a second semiconductor region 332 (a base region) of a second conductivity type, and a third semiconductor region 333 (a source region) of the first conductivity type are provided in the element portion 33 of the semiconductor substrate 30. In this example, the first conductivity type is an n-type and the second conductivity type is a p-type. In other examples, the first conductivity type may be a p-type and the second conductivity type may be an n-type.

The first semiconductor region 331 is provided above the first electrode 10 (a drain electrode). The first semiconductor region 331 comes into contact with the first electrode 10 and is electrically connected to the first electrode 10. The second semiconductor region 332 is provided above the first semiconductor region 331. The second semiconductor region 332 comes into contact with the first semiconductor region 331 and is electrically connected to the first semiconductor region 331. The third semiconductor region 333 is provided above the second semiconductor region 332. The third semiconductor region 333 comes into contact with the second semiconductor region 332 and is electrically connected to the second semiconductor region 332. An n-type impurity concentration (atoms/cm³) in the third semiconductor region 333 is higher than an n-type impurity concentration (atoms/cm³) in the first semiconductor region 331. The second electrode 20 is provided above the third semiconductor region 333. The second electrode 20 comes into contact with the third semiconductor region 333 and is electrically connected to the third semiconductor region 333.

Also, a conductive portion 41 (a gate), a conductive portion 42 (a field plate), an insulating portion 51 (a gate insulating film), an insulating portion 52, an insulating portion 53, and an insulating portion 54 are provided in the element portion 33. The conductive portion 41 faces a portion of the first semiconductor region 331, the second semiconductor region 332, and a portion of the third semiconductor region 333 across the insulating portion 51 in the X direction. Also, the conductive portion 41 is positioned below the second electrode 20 across the insulating portion 54. The conductive portion 41 is isolated from the semiconductor substrate 30 and the second electrode 20. The conductive portion 41 is electrically connected to the third electrode 25 via a wiring not depicted in the figure.

The conductive portion 42 faces the first semiconductor region 331 across the insulating portion 52. In this example, the conductive portion 42 is positioned below the conductive portion 41 with the insulating portion 53 between. The conductive portion 42 is isolated from the conductive portion 41 and the semiconductor substrate 30.

In fabrication, a trench Tr1 is formed in the semiconductor substrate 30. The trench Tr1 extends from an upper face of the third semiconductor region 333 into the first semiconductor region 331. The insulating portion 51 and the insulating portion 52 are provided on an inner wall of the trench Tr1. The conductive portion 41 and the conductive portion 42 are provided on inner sides of the insulating portion 51 and the insulating portion 52.

The structure in FIG. 5 is provided repeatedly spaced in the X direction. The depicted structure in FIG. 5 extends in the Y direction. That is, a plurality of trenches Tr1, a plurality of conductive portions 41, a plurality of conductive portions 42, and the like are arranged spaced from each other in the X direction. Each trench Tr1, each conductive portion 41, and each conductive portion 42 extends in the Y direction.

The voltage of the conductive portion 41 is controlled by a voltage between the third electrode 25 and the second electrode 20, whereby a switching on and off of the transistor is controlled. When the voltage of the third electrode 25 exceeds a threshold voltage, the transistor is switched on. For example, an on-state current flows from the first electrode 10 to the second electrode 20 via the first semiconductor region 331, the second semiconductor region 332, and the third semiconductor region 333. When the voltage of the third electrode 25 is equal to or less than the threshold voltage, the transistor is in an off-state, and the on-state current does not flow.

In this way, the element portion 33 includes the second semiconductor region 332 and the third semiconductor region 333. Also, the conductive portion 41 is provided in the element portion 33. The element portion 33 coincides with the second electrode 20 and the third electrode 25 in the Z direction. The second semiconductor region 332, the third semiconductor region 333, and the conductive portion 41 are not provided in either of the first end portion 31 or the second end portion 32. The first end portion 31 and the second end portion 32 do not coincide (overlap) with the second electrode 20 or the third electrode 25 in the z direction. The second semiconductor region 332, the third semiconductor region 333, and the conductive portion 41 need not be provided in either of the first portion 301 or the second portion 302 corresponding to where the ridge portions are provided. The first portion 301 and the second portion 302 need not coincide (overlap) with the second electrode 20 or the third electrode 25 in the Z direction.

An example of materials for each element of the semiconductor device 100 will be described.

The first electrode 10 and the second electrode 20 can comprise a metal such as aluminum.

The conductive portion 41 and the conductive portion 42 comprise a conductive material such as polysilicon.

The insulating portion 51, the insulating portion 52, the insulating portion 53, and the insulating portion 54 comprise an insulating material such as silicon oxide or silicon nitride.

The semiconductor substrate 30 comprises silicon as a semiconductor material. Arsenic, phosphorus, or antimony can be used as an n-type impurity. Boron can be used as a p-type impurity.

A solder is used for the connecting material 40.

The conductive member 60 and the conductive member 61 comprise a metal such as aluminum, copper, or iron.

Advantages of an example embodiment will be described.

When a semiconductor substrate becomes thinner, an elastic modulus of the semiconductor substrate decreases, and a strength of the semiconductor substrate decreases. Because of this, there is concern that cracking or warping of the semiconductor substrate will occur. For example, a silicon chip is such that when its thickness is less than 50 μm, the elastic modulus may decrease significantly. In response to this concern, the semiconductor substrate 30 includes the first ridge portion 311 and the second ridge portion 312. The semiconductor substrate 30 is thus partially thickened by the first ridge portion 311 and the second ridge portion 312. Because of this, the strength of the semiconductor substrate 30 can be increased.

Also, as described in relation to FIG. 1, the thickness T33 of the element portion 33 is less than the thickness T1 (the total of the thickness of the first portion 301 and the thickness of the first ridge portion 311). Because of this, an on-state resistance of the semiconductor element provided in the element portion 33 can be reduced. The semiconductor device 100 has a structure such that the substrate is thin in a device region, but chip strength is secured by ridges in end portions. According to the embodiment, a decrease in strength can be avoided, while still reducing on-state resistance.

Also, as described in relation to FIG. 2, the first side 30a is positioned in the first end portion 31 and may be longer than the third side 30c. The first ridge portion 311 extends along the first side 30a. That is, when the semiconductor substrate 30 is of a rectangular form, the long side is thickened by providing the first ridge portion 311. Because of this, the strength can be further increased.

In the plan view represented in FIG. 2, the first ridge portion 311 extends from the third side 30c to the fourth side 30d. By providing the first ridge portion 311 over a wide region in this way, the strength can be further increased.

Also, as described in relation to FIG. 1, the first electrode 10 may be provided continuously below the element portion 33, the first ridge portion 311, the second ridge portion 312, the first end portion 31, and the second end portion 32. Also, the lower face 10s of the first electrode 10 has a shape matching the shape of the lower face 30s of the semiconductor substrate 30. In this way, the first electrode 10 covers substantially the whole of the lower face 30s. Because of this, connection of the semiconductor substrate 30 and the conductive member 60 by the connecting material 40 (a mounting material such as solder), as represented in FIG. 3, is facilitated. For example, because the first electrode 10 comprises a metal, wettability of the first electrode 10 with respect to the connecting material 40 is higher than wettability of the semiconductor substrate 30 with respect to the connecting material 40. Because of this, the connecting material 40 and the first electrode 10 are more easily connected.

Also, as described in relation to FIG. 3, the connecting material 40 comes into contact with the region 10e (a first conductive region), the region 10c (a second conductive region), and the region 10a (a third conductive region) of the first electrode 10. Herein, as already described, the first ridge portion 311 protrudes farther downward than the first end portion 31 from the first portion 301. In other words, a step is formed between the first ridge portion 311 and the first end portion 31. Because of this, a creeping up of the connecting material 40 onto the side face 30e of the semiconductor substrate 30 can be restricted.

A ridge portion can be provided in a lower portion of the semiconductor substrate 30 in such a way as to enclose the element portion 33 of the semiconductor substrate 30 when seen in plan view. For example, thickening four sides of the semiconductor substrate 30 by inclusion of ridge portions is conceivable. In such a case, however, when air is initially between the element portion 33 and the connecting material 40, the air will be enclosed/blocked by the ridge portions. As such, it will be difficult to release the air from the enclosure to the exterior during manufacturing. Because of this, there is concern that a void will be left. In view of this concern, the embodiment is such that, as described in relation to FIG. 2, the whole of the region 30sa of the lower face 30s of the semiconductor substrate 30 is not enclosed by ridge portions. That is, a ridge portion (protruding portion) provided on the lower face side of the semiconductor substrate 30 is not of a form that encloses the element portion 33 when seen in plan view. Thus, when air is between the element portion 33 and the connecting material 40, the air can be released to the exterior from a Y-direction end, whereby formation of a void can be avoided.

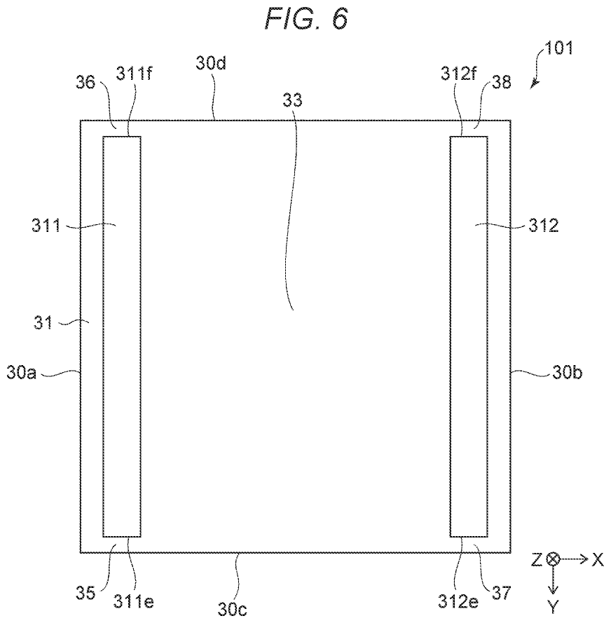

FIG. 6 is a schematic plan view depicting a modification of the embodiment.

FIG. 6 depicts a semiconductor device 101 according to a modification of the embodiment as seen from below, in a manner similar to FIG. 2 for semiconductor device 100. In this example, one end 311e of the first ridge portion 311 in the Y direction is between the third side 30c and the fourth side 30d. Another end 311f of the first ridge portion 311 in the Y direction is between the one end 311e and the fourth side 30d. Similarly, one end 312e of the second ridge portion 312 in the Y direction is between the third side 30c and the fourth side 30d. Another end 312f of the second ridge portion 312 in the Y direction is between the one end 312e and the fourth side 30d. In this case, the creeping up of the connecting material 40 onto the side face of the semiconductor substrate 30 can be further avoided.

For this semiconductor substrate 30, a region 35 between the one end 311e of the first ridge portion 311 and the third side 30c and a region 36 between the other end 311f and the fourth side 30d are provided. For this the semiconductor substrate 30, a region 37 between the one end 312e of the second ridge portion 312 and the third side 30c and a region 38 between the other end 312f and the fourth side 30d are provided. That is, the first ridge portion 311 and the second ridge portion 312 do not extend for the full length of the semiconductor substrate 30 in the Y direction.

Next, a method of manufacturing the semiconductor device 100 will be described.

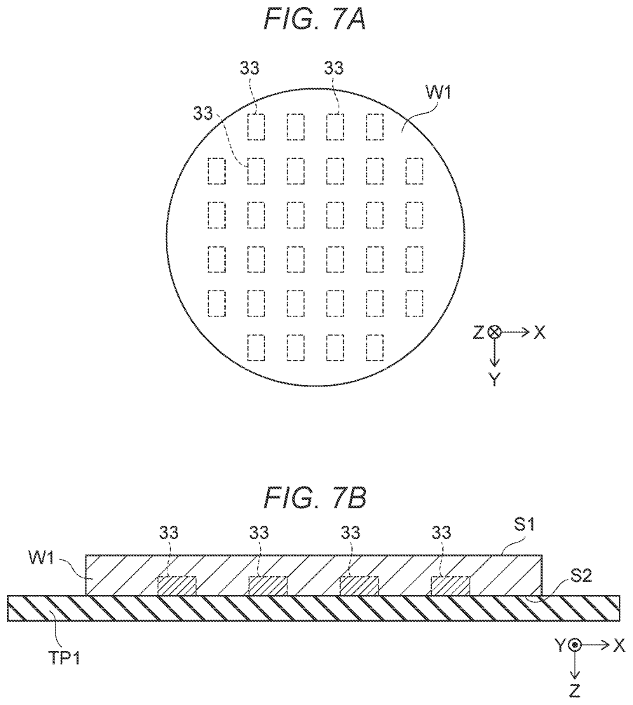

FIGS. 7A and 7B, FIGS. 8A and 8B, FIGS. 9A to 9C, FIGS. 10A and 10B, and FIGS. 11A to 11C are schematic views depicting aspects of a semiconductor device manufacturing method according to an embodiment. The drawings represent a method of manufacturing the semiconductor device 100 in a general order of processing.

As represented in FIG. 7A, a wafer W1 (a semiconductor wafer) pieces of which are to become a semiconductor substrate 30 is prepared. FIG. 7B depicts a cross-section of FIG. 7A. The wafer W1 has a first face S1 (corresponding to the lower face 30s in FIG. 1) and a second face S2 (corresponding to the upper face 30t in FIG. 1). Multiple element portions 33 are arranged along the X direction and the Y direction on the wafer W1. Although specific depiction is omitted, the second electrode 20 is formed on the second face S2 side of each element portion 33.

As represented in FIG. 7B, the second face S2 of the wafer W1 is affixed to a tape TP1. Further, the first face S1 side is ground (polished), thereby thinning the wafer W1 in a backgrinding (BG) process.

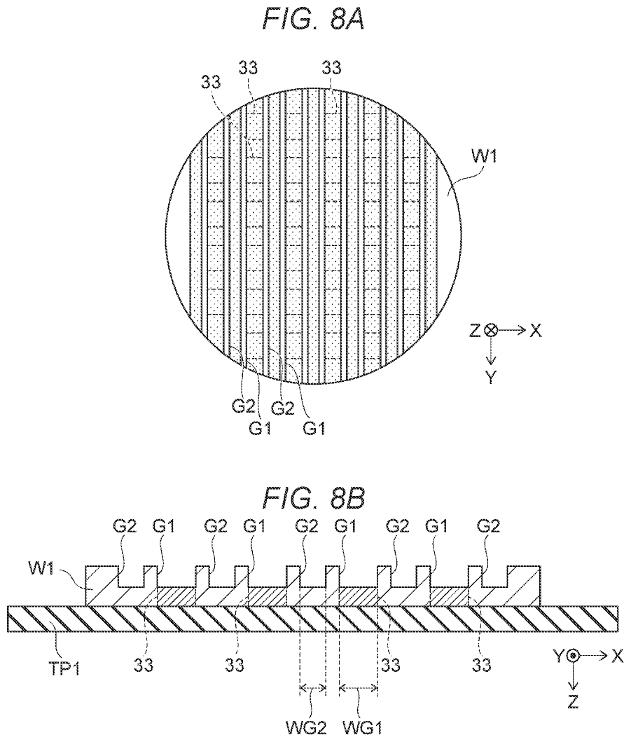

Subsequently, as represented in FIG. 8A, first grooves G1 and second grooves G2 are formed in the first face S1 of the wafer W1. FIG. 8B depicts a cross-section of FIG. 8A.

The first grooves G1 are arranged in the X direction, and each first groove G1 extends in the Y direction. A position of at least one portion of each first groove G1 in the X direction is the same as a position of at least one portion of one element portion 33 in the X direction. For example, each first groove G1 is provided in such a way as to coincide in the Z direction with a whole one of the element portions 33 arranged in the Y direction.

The second grooves G2 are arranged in the X direction, and each second groove G2 extends in the Y direction. S grooves G2 are positioned between otherwise adjacent two first grooves G1. No second groove G2 coincides (overlaps) with an element portion 33 in the Z direction. The first grooves G1 and the second grooves G2 are provided alternately with each other in the X direction. In this example, depths of the first grooves G1 and the second grooves G2 are all the same.

For example, a width WG1 (a length along the X direction) of the first groove G1 may be the same as a width WG2 (a length along the X direction) of the second groove G2. In other examples, these widths may differ from each other. In the example represented in FIG. 8B, the width WG1 is greater than the width WG2.

A mechanical processing can be used in a formation of the first groove G1 and the second groove G2. For example, the first groove G1 and the second groove G2 are formed by cutting the wafer W1 with a blade (sawblade). Alternatively, the first groove G1 and the second groove G2 may be formed by a wet etching process. In this example, there is no groove extending lengthwise in the X direction to be provided in the wafer W1. Because of this, the manufacturing process can be simplified since grooves all extend in one direction.

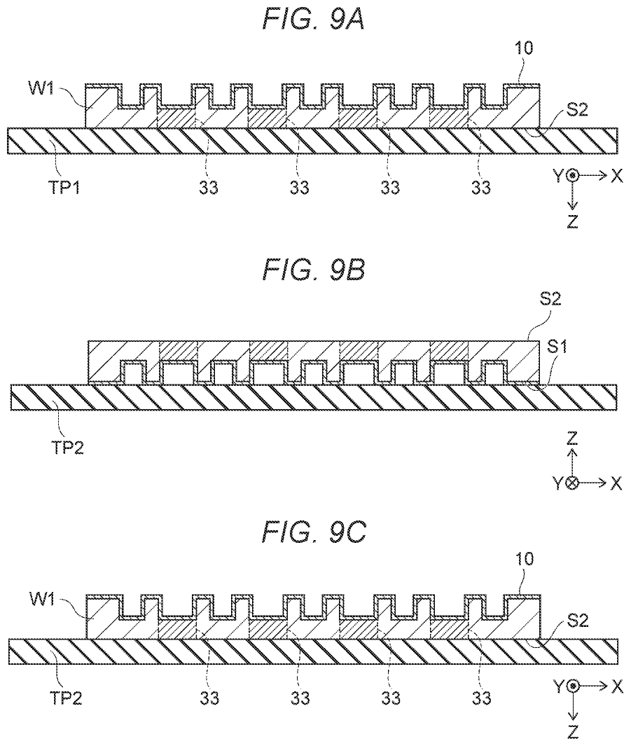

After the formation of the first grooves G1 and the second grooves G2, a fractured layer that may be generated in the formation of the grooves can be removed. Next, the first electrode 10 is formed using, for example, a sputtering method on the first face S1, as represented in FIG. 9A.

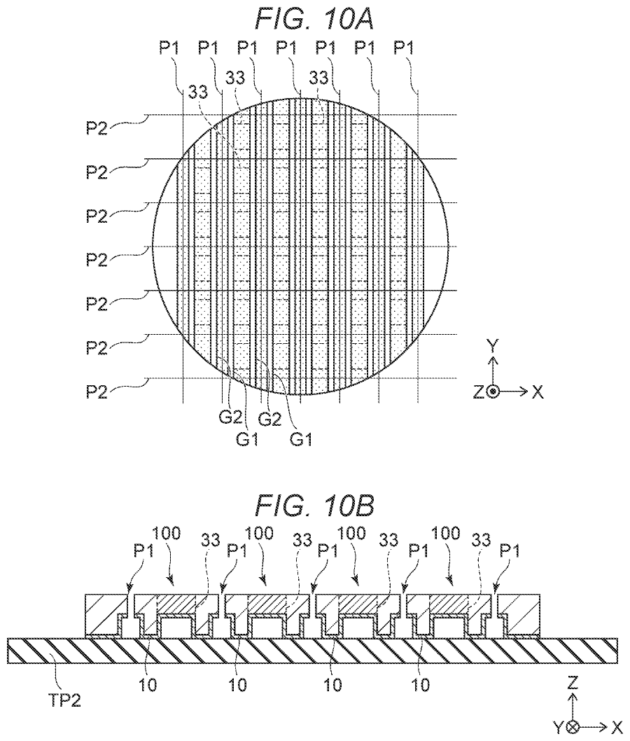

Subsequently, as represented in FIG. 9B, the wafer W1 is transferred to a tape TP2 (a dicing tape). That is, the wafer W1 is detached from the tape TP1, and the first face S1 side of the wafer W1 is now affixed to the tape TP2. The wafer W1 may then be transferred again to a different tape TP2, as represented in FIG. 9C. That is, another tape TP2 may be affixed to the second face S2 side of the wafer W1, and the tape TP2 that was affixed to the first face S1 side may be detached. FIGS. 10A and 10B depict a case in which a dicing process is executed on the wafer W1 in the state of FIG. 9B, that is, without the retransferring of FIG. 9C being executed.

Subsequently, as represented in FIG. 10A, the wafer W1 is separated/diced at multiple first positions P1 and multiple second positions P2 (via a dicing process). By so doing, the wafer W1 is divided into multiple chips (e.g., semiconductor devices 100). FIG. 10B depicts a cross-section of FIG. 10A. Each of the chips thus formed includes an element portion 33.

Each first position P1 is a position at which the second groove G2 is provided. That is, the first position P1 coincides with the second groove G2 in the Z direction, and similarly extends in the Y direction. Each second position P2 is positioned between two adjacent element portions 33 that neighbor each other in the Y direction and extends in the X direction. A wafer W1 retransferred as shown in FIG. 9C permits the wafer W1 to be separated in the same way at the first position P1 and the second position P2.

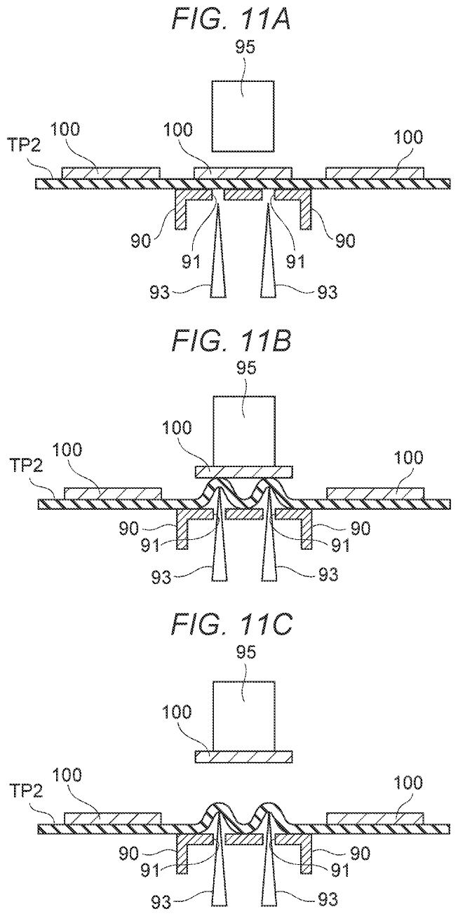

Subsequently, as represented in FIGS. 11A to 11C, each chip (semiconductor device 100) is picked up and detached from the tape TP2 (in a pick-up process).

As represented in FIG. 11A, the tape TP2 and the semiconductor device 100 are placed on a stage 90 in which at least one hole 91 is provided. A pin 93 is passed through the hole 91 from below the stage 90 and brought into contact with the tape TP2.

As represented in FIG. 11B, the semiconductor device 100 is pushed upward by the pin(s) 93 from across the tape TP2. Because of this, the tape TP2 bends, and an end portion of the semiconductor device 100 is detached from the tape TP2. Also, in this process, the semiconductor device 100 can be suctioned from above by a collet 95.

The semiconductor device 100 is lifted up by the collet 95 while being pushed upward by the pin(s) 93. The semiconductor device 100 can thus be picked up (detached), as represented in FIG. 11C.

This kind of pick-up process is such that when a semiconductor substrate is thin, there is concern that the semiconductor substrate may warp (flex) and break. Also, there is concern that a chip will break (fracture) with a position in contact with a pin 93 as a starting point.

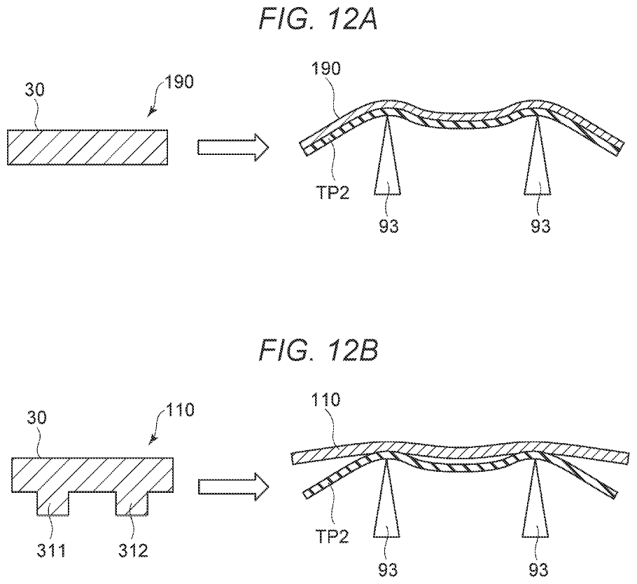

FIGS. 12A and 12B are schematic views illustrating a pick-up of a semiconductor device.

A semiconductor device 190 represented in FIG. 12A is a chip in which the first ridge portion 311 and the second ridge portion 312 are not provided. A semiconductor device 110 represented in FIG. 12B differs from the semiconductor device 190 in that the first ridge portion 311 and the second ridge portion 312 are provided.

As represented in FIG. 12A, the semiconductor device 190 is such that when the tape TP2 bends due to a pushing up by the pin 93 during picking up, the chip is liable to deform. Because of this the chip may break without being detached from the tape.

In contrast to this, as represented in FIG. 12B, the semiconductor device 110 is such that when the tape TP2 bends due to a pushing up by the pin 93 during picking up, the chip is less likely to deform. Because of this the chip is more easily detached from the tape without breakage or the like.

In this way, according to an embodiment, chip warping during picking up and chip damage caused by pin push up can be reduced by providing the first ridge portion 311 and the second ridge portion 312, thereby thickening (strengthening) at least one portion of the semiconductor substrate 30.

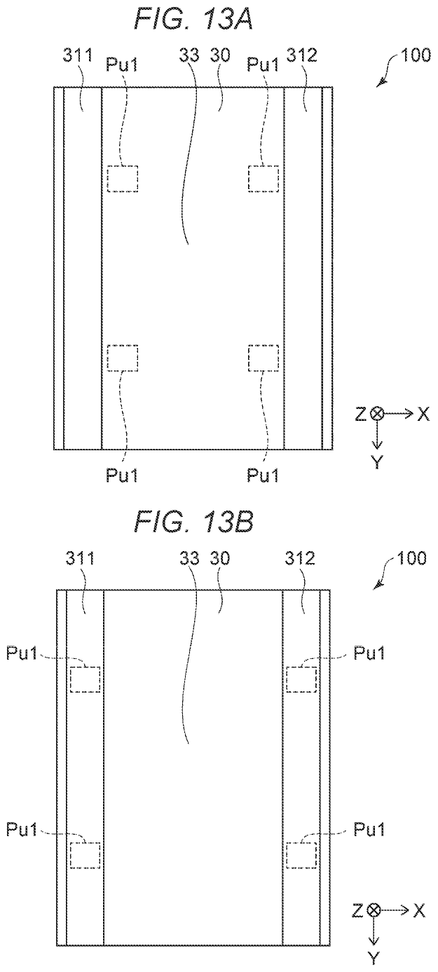

FIGS. 13A and 13B are schematic plan views exemplifying a pushing up position used during a picking up process of a semiconductor device.

FIGS. 13A and 13B each represent a case in which the semiconductor device 100 is seen from below, in a manner similar to FIG. 2.

As represented in FIGS. 13A and 13B, the semiconductor device 100 is pushed up by the pins 93 in four push-up positions Pu1. The push-up positions Pu1 may be between the first ridge portion 311 and the second ridge portion 312 when seen in plan view, as in FIG. 13A.

The push-up positions Pu1 may instead be positioned in the first ridge portion 311 and the second ridge portion 312 when seen in plan view, as in FIG. 13B. In this case, a thicker portion of the semiconductor substrate 30 will be pushed up by the pins 93 rather than a thin portion. Because of this, chip damage caused by the pins 93 pushing up can be further avoided.

According to an embodiment, a semiconductor device whose strength can be increased, and a manufacturing method thereof, can be provided.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate having an upper face and a lower face, the upper face being opposite of the lower face in a first direction, the semiconductor substrate including:
a first end portion near a first edge of the semiconductor substrate,
a second end portion near a second edge of the semiconductor substrate, the first edge and the second edge being separated from each other in a second direction orthogonal to the first direction,
an element region between the first end portion and the second end portion in the second direction,
a first ridge portion that protrudes in the first direction from a first portion that is between the first end portion and the element portion in the second direction, the first ridge portion being on the lower face and extending along the lower face in a third direction perpendicular to the first direction and the second direction, and
a second ridge portion that protrudes in the first direction from a second portion that is between the second end portion and the element portion in the second direction, the second ridge portion being on the lower face and extending along the lower face in the third direction.

2. The semiconductor device according to claim 1, wherein the semiconductor substrate is substantially rectangular in planar shape when viewed from the first direction.

3. The semiconductor device according to claim 2, wherein
the first edge extends in the third direction,
the second edge extends in parallel with first edge, and
the semiconductor substrate further includes:
a third edge extending in the second direction and meeting the first edge at a first corner and the second edge at a second corner, and
a fourth edge extending in the second direction and meeting the first edge at a third corner and the second edge at a fourth corner.

4. The semiconductor device according to claim 3, wherein
the first edge is equal in length to the second edge,
the first edge is longer than the third edge, and
the first edge is longer than the fourth edge.

5. The semiconductor device according to claim 3, wherein the first ridge portion extends from the third edge to the fourth edge.

6. The semiconductor device according to claim 3, wherein the lower surface of the semiconductor substrate between the first ridge portion and the second ridge portion is substantially flat from the third edge to the fourth edge.

7. The semiconductor device according to claim 1, wherein the first ridge portion extends parallel to the first edge from an outermost edge of the semiconductor substrate to an opposite outermost edge of the semiconductor substrate.

8. The semiconductor device according to claim 1, wherein the first ridge portion extends parallel to the first edge but an end of the first ridge portion is offset in the third direction from an outermost edge of the semiconductor substrate.

9. The semiconductor device according to claim 1, further comprising:
a first electrode on the lower face of the semiconductor substrate; and
a second electrode on the upper face of the semiconductor substrate covering the element portion.

10. The semiconductor device according to claim 9, wherein a thickness of the element portion is less than a summed total of a thickness of the first portion and the first ridge portion along the first direction.

11. The semiconductor device according to claim 9, wherein the first electrode is a continuous film on the element portion, the first ridge portion, the second ridge portion, the first end portion, and the second end portion.

12. The semiconductor device according to claim 11, further comprising:
a conductive connecting material connecting the first electrode to a conductive member below the semiconductor substrate in the third direction.

13. The semiconductor device according to claim 12, wherein
the first electrode includes a first conductive region that covers the element portion, a second conductive region that covers the first ridge portion, and a third conductive region that covers the first end portion, and
the connecting material contacts the first conductive region, the second conductive region, and the third conductive region.

14. The semiconductor device according to claim 1, wherein the lower face of the semiconductor substrate is substantially flat at all positions between the first ridge portion and the second ridge portion in the second direction.

15. A semiconductor device, comprising:
a semiconductor substrate having a first electrode on a lower face and a second electrode on an upper face; and
a conductive member joined to the lower face by a conductive material, wherein
the semiconductor substrate has:
a first end region near a first outer edge of the semiconductor substrate,
a second end region near a second outer edge of the semiconductor substrate, the first outer edge and the second outer edge being separated from each other in a second direction orthogonal to the first direction,
an element region between the first end region and the second end region in the second direction,
a first ridge between the first end region and the element portion, the first ridge extending along the lower face in a third direction perpendicular to the first direction and the second direction, and
a second ridge between the second end region and the element portion in the second direction, the second ridge extending along the lower face in the third direction.

16. The semiconductor device according to claim 15, wherein the first electrode is a metal film covering the lower face of the semiconductor substrate including the first ridge, the second ridge, the first end region, and the second end region.

17. The semiconductor device according to claim 15, wherein the lower face of the semiconductor substrate is substantially flat at all positions between the first ridge and the second ridge in the second direction.

18. The semiconductor device according to claim 15, wherein the first ridge and the second ridge extend along the lower face of the semiconductor substrate in the third direction for the full dimension of the semiconductor substrate in the third direction.

19. A semiconductor device manufacturing method, comprising:
obtaining a wafer having a first face and a second face, the first face being opposite of the second face in a first direction, the wafer having a plurality of element regions, the plurality of element regions being arranged in a second direction and a third direction parallel to the first face;
forming first grooves in the second face of the wafer, each first groove extending lengthwise in the third direction and being positioned to coincide with element regions in the plurality of element regions aligned along the third direction;
forming second grooves in the second face of the wafer, each second groove extending lengthwise in the third direction and being between an otherwise adjacent pair of first grooves; and
dicing the wafer at a first position coinciding with a second groove.

20. The semiconductor device manufacturing method according to claim 19, further comprising:
forming a metallic electrode film on the second face after forming the first and second grooves.
